(19) United States
(12) Patent Application Publication
(10) Pub. No.: US 2023/0230842 A1
(43) Pub. Date: Jul. 20, 2023

(54) PATTERNING METHOD AND METHOD OF MANUFACTURING SEMICONDUCTOR STRUCTURE

(71) Applicant: CHANGXIN MEMORY TECHNOLOGIES, INC., Hefei City (CN)

(72) Inventors: Juanjuan HUANG, Hefei City (CN); Jie BAI, Hefei City (CN)

(21) Appl. No.: 18/149,210

(22) Filed: Jan. 3, 2023

(30) Foreign Application Priority Data
Jan. 17, 2022 (CN) 202210048954.4

(51) Int. Cl. H01L 21/308; H10B 12/00; H01L 21/306; H01L 21/311

(52) U.S. Cl. CPC H01L 21/3086; H01L 21/3088; H01L 21/3081; H10B 12/01; H01L 21/30604; H01L 21/31111; H01L 21/31144

(57) ABSTRACT

The present disclosure relates to a patterning method and a method of manufacturing a semiconductor structure. The patterning method includes: providing a base; forming a first patterned mask layer on a surface of the base, where the first patterned mask layer includes a plurality of first mask structures extending along a first direction, and the first mask structures are arranged at intervals; forming a first dielectric layer on the first patterned mask layer, where the first dielectric layer fills up a spacing region between the first mask structures and covers an upper surface of the first patterned mask layer; and etching the first dielectric layer to form a plurality of second mask structures extending along a second direction, where the second mask structures are arranged at intervals, and the second direction intersects with the first direction; and selectively etching the first mask structure and the second mask structure.

### CROSS-REFERENCE TO RELATED APPLICATION

This application claims the priority of Chinese Patent Application No. 202210048954.4, submitted to the Chinese Intellectual Property Office on Jan. 17, 2022, the disclosure of which is incorporated herein in its entirety by reference.

### TECHNICAL FIELD

The present disclosure relates to the technical field of semiconductors, and in particular to a patterning method and a method of manufacturing a semiconductor structure.

### BACKGROUND

Reduction of a feature dimension has been a trend in the development of dynamic random access memory (DRAM) technologies. After the feature dimension is reduced to a limit of a lithography machine, a pattern density should be increased using auxiliary techniques, such as a self-aligned double patterning (SADP) process, a lithography-etch-lithography-etch (LELE) process, and a self-aligned quadruple patterning (SAQP) technique. However, LELE requires the execution of two lithography processes, which require high precision alignment. Therefore, LELE requires extremely high precision, making it impossible to continuously perform density multiplication. Meanwhile, in a conventional SADP process of making fine patterns, etching needs to be performed a plurality of times to form a patterned mask structure, leading to a complicated overall process.

### SUMMARY

Based on this, it is necessary to provide a patterning method and a method of manufacturing a semiconductor structure, to resolve the foregoing problem.

The present application discloses a patterning method, including: providing a base; forming a first patterned mask layer on a surface of the base, where the first patterned mask layer includes a plurality of first mask structures extending along a first direction, and the first mask structures are arranged at intervals; forming a first dielectric layer on the first patterned mask layer, where the first dielectric layer fills up a spacing region between the first mask structures and covers an upper surface of the first patterned mask layer; and etching the first dielectric layer to form a plurality of second mask structures extending along a second direction, where the second mask structures are arranged at intervals, and the second direction intersects with the first direction; and selectively etching the first mask structure and the second mask structure, to form a mesh-shaped mask layer on the surface of the base.

The present application further discloses a method of manufacturing a semiconductor structure, including: forming a pattern transfer layer on a base; forming the mesh-shaped mask layer on an upper surface of the pattern transfer layer by using the patterning method according to any one of the foregoing embodiments, where the mesh-shaped mask layer exposes the pattern transfer layer; etching the pattern transfer layer based on the mesh-shaped mask layer; and removing the mesh-shaped mask layer.

### BRIEF DESCRIPTION OF THE DRAWINGS

FIG. 1 is a flow block diagram of a patterning method according to an embodiment of the present application;

FIG. 2 is a schematic diagram of a cross-sectional structure of a semiconductor structure obtained after a first mask layer is formed on a surface of a base according to an embodiment of the present application;

FIG. 3A is a top view obtained after a first mask is provided on a first mask layer according to an embodiment of the present application, and FIG. 3B is a schematic diagram of a cross-sectional structure along an AA′ direction in FIG. 3A;

FIG. 4A is a top view obtained after first mask structures are formed according to an embodiment of the present application, and FIG. 4B is a schematic diagram of a cross-sectional structure along an AA′ direction in FIG. 4A;

FIG. 5A is a top view obtained after a first dielectric layer is formed according to an embodiment of the present application, and FIG. 5B is a schematic diagram of a cross-sectional structure along an AA′ direction in FIG. 5A;

FIG. 6A is a top view obtained after a second mask is provided on a first dielectric layer according to an embodiment of the present application, and FIG. 6B is a schematic diagram of a cross-sectional structure along an AA′ direction in FIG. 6A;

FIG. 7A is a top view obtained after second mask structures are formed according to an embodiment of the present application, and FIG. 7B is a schematic diagram of a cross-sectional structure along an AA′ direction in FIG. 7A;

FIG. 8A is a top view obtained after a second dielectric layer is etched to expose second mask structures according to an embodiment of the present application, and FIG. 8B is a schematic diagram of a cross-sectional structure along an AA′ direction in FIG. 8A;

FIG. 9A is a top view obtained after part of second mask structures is removed based on a second dielectric layer according to an embodiment of the present application, and FIG. 9B is a schematic diagram of a cross-sectional structure along an AA′ direction in FIG. 9A;

FIG. 10A is a top view obtained after part of first mask structures is removed based on a second dielectric layer according to an embodiment of the present application, and FIG. 10B is a schematic diagram of a cross-sectional structure along an AA′ direction in FIG. 10A;

FIG. 11A is a top view obtained after a mesh-shaped mask layer is formed according to an embodiment of the present application, FIG. 11B is a schematic diagram of a cross-sectional structure along an AA′ direction in FIG. 11A, FIG. 11C is a schematic diagram of a cross-sectional structure along a BB′ direction in FIG. 11A, and FIG. 11D is a schematic diagram of a cross-sectional view along a CC′ direction in FIG. 11A;

FIG. 12 is a schematic diagram of a cross-section of a semiconductor structure obtained after a pattern transfer layer is formed on a surface of a base according to an embodiment of the present application;

FIG. 13A is a top view obtained after a mesh-shaped mask layer is formed on a surface of a pattern transfer layer according to an embodiment of the present application, and FIG. 13B is a schematic diagram of a cross-sectional structure along a BB′ direction in FIG. 13A;

FIG. 14A is a top view obtained after a pattern transfer layer is etched based on a mesh-shaped mask layer according to an embodiment of the present application, and FIG. 14B is a schematic diagram of a cross-sectional structure along a BB′ direction in FIG. 14A;

FIG. 15A is a top view obtained after a mesh-shaped mask layer is removed according to an embodiment of the present application, and FIG. 15B is a schematic diagram of a cross-sectional structure along a BB′ direction in FIG. 15A;

FIG. 16A is a top view obtained after a patterned hard mask layer is formed on a surface of a base according to an embodiment of the present application, and FIG. 16B is a schematic diagram of a cross-sectional structure along a BB′ direction in FIG. 16A;

FIG. 17 is a schematic diagram of a cross-sectional structure of a semiconductor structure obtained after a hard mask layer is formed according to an embodiment of the present application;

FIG. 18 is a schematic diagram of a cross-sectional structure of a semiconductor structure obtained after a pattern transfer layer is formed on a hard mask layer according to an embodiment of the present application;

FIG. 19A is a top view obtained after a mesh-shaped mask structure is formed on a hard mask layer according to an embodiment of the present application, and FIG. 19B is a schematic diagram of a cross-sectional structure along a BB′ direction in FIG. 19A;

FIG. 20 and FIG. 21 are each a schematic flowchart of adjusting a size of a mesh in a mesh-shaped mask structure according to an embodiment of the present application;

FIG. 22A is a top view obtained after linear structures in a patterned hard mask layer are cut off according to an embodiment of the present application, and FIG. 22B is a schematic diagram of a cross-sectional structure along a BB′ direction in FIG. 22A;

FIG. 23 is a schematic diagram of a cross-sectional structure of a semiconductor structure obtained after active regions are formed in a base according to an embodiment of the present application;

FIG. 24 is a schematic diagram of a cross-sectional structure of a semiconductor structure obtained after a metal layer and a hard mask layer are formed on a surface of a base according to an embodiment of the present application;

FIG. 25 is a schematic diagram of a cross-sectional structure of a semiconductor structure obtained after a pattern transfer layer is formed on a surface of a hard mask layer according to an embodiment of the present application;

FIG. 26A is a top view obtained after a mesh-shaped mask structure is formed in a pattern transfer layer according to an embodiment of the present application, and FIG. 26B is a schematic diagram of a cross-sectional structure along a BB′ direction in FIG. 26A;

FIG. 27A is a top view obtained after a mesh-shaped mask structure is etched to form columnar structures according to an embodiment of the present application, and FIG. 27B is a schematic diagram of a cross-sectional structure along a BB′ direction in FIG. 27A; and

FIG. 28A is a top view obtained after a metal layer is etched based on columnar structures to form a metal pad according to an embodiment of the present application, and FIG. 28B is a schematic diagram of a cross-sectional structure along a BB′ direction in FIG. 28A.

### DETAILED DESCRIPTION

To facilitate the understanding of the present disclosure, the present disclosure is described more completely below with reference to the accompanying drawings. The preferable embodiments of the present disclosure are shown in the accompanying drawings. However, the present disclosure is embodied in various forms without being limited to the embodiments set forth herein. On the contrary, these embodiments are provided to make the understanding of the disclosed content of the present disclosure more thorough and comprehensive.

Unless otherwise defined, all technical and scientific terms used herein have the same meaning as commonly understood by those skilled in the technical field of the present disclosure. The terms mentioned herein are merely for the purpose of describing specific embodiments, rather than to limit the present disclosure. The term “and/or” used herein includes any and all combinations of one or more of the associated listed items.

In the description of a position relationship, unless otherwise specified, when one element, such as a layer, film, or substrate, is referred to as being “on” another film layer, it can be directly located on the another film layer or there may be an intermediate film layer. Further, when a layer is referred to as being “under” another layer, it can be directly under the another layer or there may be one or more intermediate layers. It can also be understood that, when a layer is referred to as being “between” two layers, it may be the only layer between the two layers or there may be one or more intermediate layers.

In a case in which terms “include”, “have”, and “contain” in the specification are used, another component can be added unless clear qualifiers such as “only” and “consist of” are used. Unless the contrary is mentioned, terms in the singular form may include the plural form but are not to be understood as a single one.

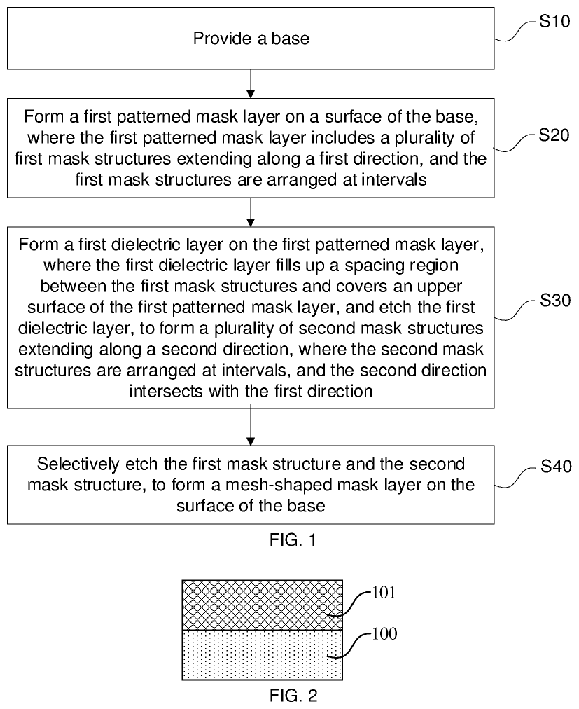

As shown in FIG. 1, an embodiment of the present application discloses a patterning method, including:

S10: Provide a base.

S20: Form a first patterned mask layer on a surface of the base, where the first patterned mask layer includes a plurality of first mask structures extending along a first direction, and the first mask structures are arranged at intervals.

S30: Form a first dielectric layer on the first patterned mask layer, where the first dielectric layer fills up a spacing region between the first mask structures and covers an upper surface of the first patterned mask layer, and etch the first dielectric layer, to form a plurality of second mask structures extending along a second direction, where the second mask structures are arranged at intervals, and the second direction intersects with the first direction.

S40: Selectively etch the first mask structure and the second mask structure, to form a mesh-shaped mask layer on the surface of the base.

In step S10, for example, the base may include but is not limited to a silicon base.

In step S20, for example, the step of forming the first patterned mask layer on the surface of the base includes:

S21: Form a first mask layer 101 on a surface of a base 100, as shown in FIG. 2.

The first mask layer 101 may include but is not limited to a silicon nitride layer. For example, the first mask layer 101 may be formed by using an atomic layer deposition (ALD) process, a chemical vapor deposition process, or a plasma vapor deposition process.

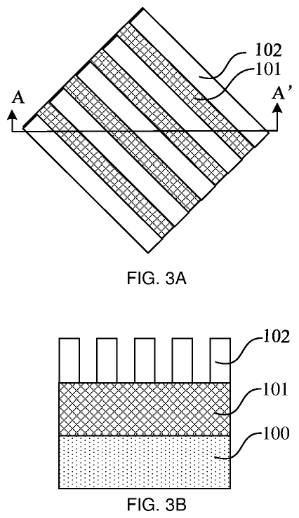

S22: Provide a first mask 102, where the first mask 102 includes a plurality of first straight line masks extending along the first direction, and the first straight line masks are arranged at intervals, as shown in FIG. 3A and FIG. 3B.

Optionally, a width of a spacing between the first straight line masks may be equal to a width of the first straight line mask. In some other implementations, a width of a spacing between the first straight line masks is not equal to a width of the first straight line mask.

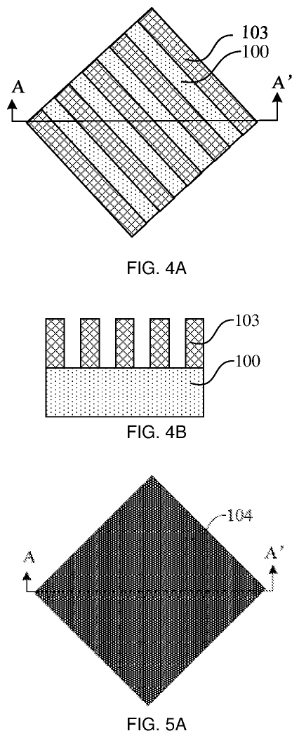

S23: Align the first mask 102 with the first mask layer 101 by using a self-aligned process, and remove the first mask layer 101 outside a shielding region of the first mask 102, to form a first patterned mask layer including first mask structure 103, as shown in FIG. 4A and FIG. 4B.

The first mask 102 can be quickly and accurately aligned with the first mask layer 101 by using the self-aligned process. A precision requirement is not high, and an operation is easily to be performed. For example, after the first mask 102 is aligned with the first mask layer 101, the first mask layer 101 outside the shielding region of the first mask 102 may be removed by using a lithography process, to form strip-shaped first mask structure 103, where all of the first mask structures collectively constitute the first patterned mask layer. The first mask structures 103 are arranged at intervals, and a trench between adjacent first mask structures exposes an upper surface of the base 100. The first mask structure 103 extends along the first direction.

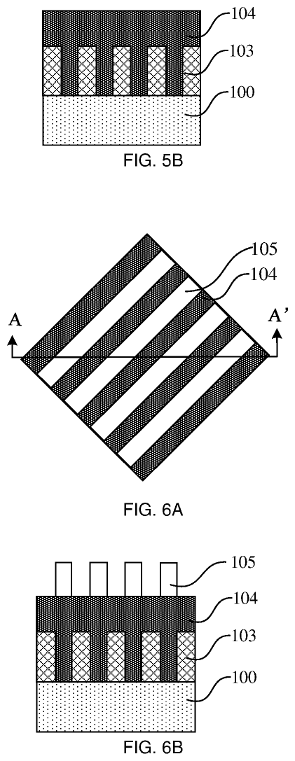

In step S30, as shown in FIG. 5A and FIG. 5B, a first dielectric layer 104 is formed on the first patterned mask layer, where the first dielectric layer 104 fills up a spacing region between the first mask structures 103 and covers the upper surface of the first patterned mask layer. For example, the first dielectric layer 104 may include but is not limited to a carbon layer. The first dielectric layer 104 may be formed by using an ALD process, a chemical vapor deposition process, or a plasma vapor deposition process.

For example, the step of etching the first dielectric layer 104 to form a plurality of second mask structures 106 extending along the second direction includes:

S31: Provide a second mask 105, where the second mask 105 includes a plurality of second straight line masks extending along the second direction, and the second straight line masks are arranged at intervals, as shown in FIG. 6A and FIG. 6B.

For example, the second direction intersects with the first direction. Optionally, the second direction is perpendicular to the first direction. Optionally, a width of a spacing between the second straight line masks is the same as a width of the second straight line mask.

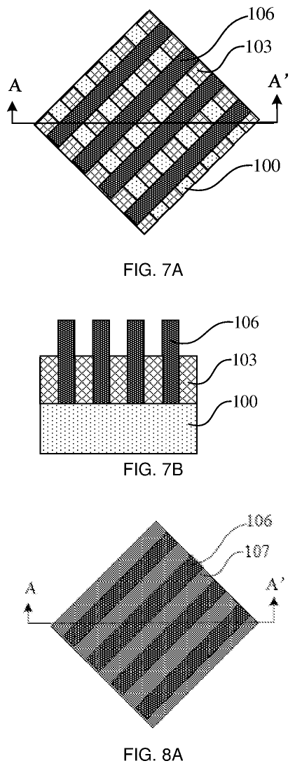

S32: Align the second mask 105 with the first dielectric layer 104 by using a self-aligned process, and remove the first dielectric layer 104 outside a shielding region of the second mask 105, to form the second mask structure 106, where a spacing region between the second mask structures 106 exposes the first patterned mask layer and the base 100, as shown in FIG. 7A and FIG. 7B.

For example, after the second mask 105 is aligned with the first dielectric layer 104, the first dielectric layer 104 outside the shielding region of the second mask 105 may be removed by using a lithography process until the first patterned mask layer and the base 100 are exposed, to form the second mask structures 106 arranged at intervals, where the second mask structures 106 extend along the second direction. The second mask structure 106 may be divided into two parts. A first part is located inside the trench between the first mask structures 103 and is flush with the upper surface of the first patterned mask layer. A second part is a strip-shaped structure extending along the second direction and is located above the first part and the first mask structure 103.

In step S40, the step of selectively etching the first mask structure 103 and the second mask structure 106, to form a mesh-shaped mask layer on the surface of the base 100 includes:

S41: Form a second dielectric layer 107, where the second dielectric layer 107 fills up the spacing region between the second mask structures 106 and covers an upper surface of the second mask structure 106.

The second dielectric layer 107 may include but is not limited to a silicon oxide layer. For example, the second dielectric layer 107 may be formed by using an ALD process, a chemical vapor deposition process, or a plasma vapor deposition process.

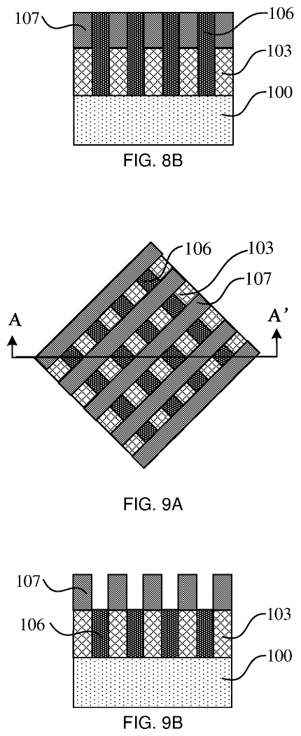

S42: Etch the second dielectric layer 107 until the upper surface of the second mask structure 106 is exposed, as shown in FIG. 8A and FIG. 8B.

S43: Selectively etch the second mask structure 106 until an upper surface of the first mask structure 103 is exposed, as shown in FIG. 9A and FIG. 9B.

For example, a gas that has a selectivity ratio only to the second mask structure 106 is selected and the second dielectric layer 107 is used as a mask, to remove the second part of the second mask structure 106 through etching, so as to expose the first mask structure 103 and the first part of the second mask structure 106.

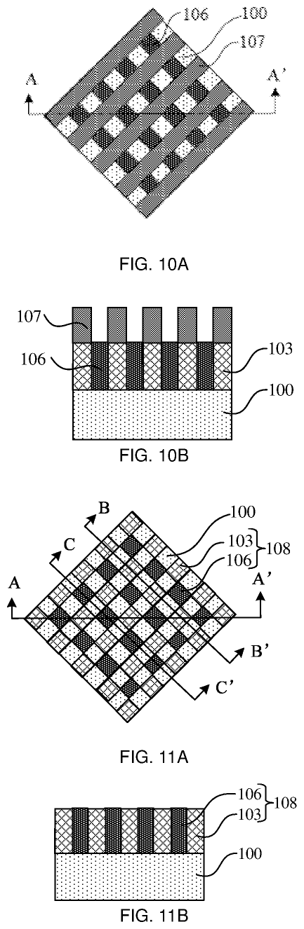

S44: Selectively etch an exposed first mask structure 103 until the surface of the base 100 is exposed, as shown in FIG. 10A and FIG. 10B.

For example, a gas that has a selectivity ratio only to the first mask structure 103 is selected and the second dielectric layer 107 and the first part of the second mask structure 106 are used as a mask, to etch the first mask structure 103, until the upper surface of the base 100 is exposed.

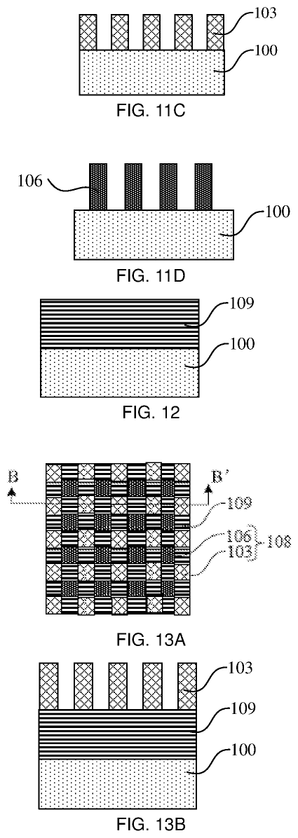

S45: Remove a remaining part of the second dielectric layer 107 to form a mesh-shaped mask layer 108, as shown in FIG. 11A to FIG. 11D.

After the remaining part of the second dielectric layer 107 is removed, it can be learned that, the first mask structures 103 originally extending along the first direction are cut, after being etched, into rectangular structures arranged at intervals, as shown in FIG. 11A. The first part of the second mask structure 106 and the remaining part of the first mask structure 103 form the mesh-shaped mask layer 108 on the surface of the base 100. A mesh in the mesh-shaped mask layer 108 exposes part of the upper surface of the base 100.

In the patterning method, the mesh-shaped mask layer 108 is formed on the surface of the base 100 by using two intersecting linear masks in combination with an etching process and a deposition process. This can increase a density of meshes in a mask pattern by three times. Compared with a conventional LELE process, a precision requirement in a process is reduced, and the process difficulty is lowered. Compared with a conventional SADP and SAQP process, steps are simplified. In addition, the method and the SADP and SAQP process may be optimally used at different technology nodes, to reduce process costs.

In some embodiments, a width of a spacing between the first mask structures 103 is equal to a width of the first mask structure 103; a width of a spacing between the second mask structures 106 is equal to a width of the second mask structure 106. Optionally, the width of the first mask structure 103 and the width of the second mask structure 106 may be equal or not be equal.

In the patterning method, the width of the mask structure and the width of the spacing between the mask structures are controlled to flexibly adjust a required size of the mesh. Further, in some implementations, an included angle between the first direction and the second direction may be further adjusted, to change a shape of the mesh.

In some embodiments, to further increase a density of meshes in the mesh-shaped mask layer 108, based on the patterning method, a density of the first mask structures 103 and/or a density of the second mask structures 106 may be multiplied by using an SADP process or an SAQP process.

For example, the density of the first mask structures 103 may be multiplied by using the SADP process or the SAQP process, to enable the width of the first mask structure 103 and the width of the spacing between the first mask structures 103 to be smaller. Optionally, the density of the second mask structures 106 may be multiplied by using the SADP process or the SAQP process, to enable the width of the second mask structure 106 and the width of the spacing between the second mask structures 106 to be smaller. Optionally, both the density of the first mask structures 103 and the density of the second mask structures 106 may be further multiplied by using the SADP process or the SAQP process, to form a mesh-shaped mask layer 108 having meshes that are denser.

The patterning method may be flexibly used in combination with the SADP process or the SAQP process to further multiply a density of meshes in a mask pattern, and has good compatibility with the conventional processes.

An embodiment of the present application further discloses a method of manufacturing a semiconductor structure, including:

S100: Form a pattern transfer layer 109 on a base 100, as shown in FIG. 12.

S200: Form a mesh-shaped mask layer 108 on an upper surface of the pattern transfer layer 109 by using the patterning method according to any one of the foregoing embodiments, where the mesh-shaped mask layer 108 exposes the pattern transfer layer 109, as shown in FIG. 13A and FIG. 13B.

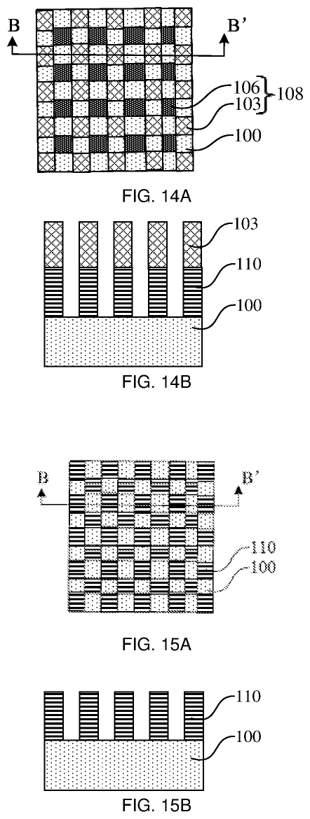

S300: Etch the pattern transfer layer 109 based on the mesh-shaped mask layer 108, and form a mesh-shaped mask structure 110 in the pattern transfer layer 109, as shown in FIG. 14A and FIG. 14B.

S400: Remove the mesh-shaped mask layer 108, to obtain a semiconductor structure shown in FIG. 15A and FIG. 15B.

For example, the base 100 may include but is not limited to a silicon base 100, and a material of the pattern transfer layer 109 is different from that of a first mask structure 103 and that of a second mask structure 106. For example, the first mask structure 103 is a silicon nitride layer, the second mask structure 106 is a carbon layer, and the pattern transfer layer 109 is a silicon oxide layer.

In the method of manufacturing a semiconductor structure, by using the patterning method in the foregoing embodiments, the mesh-shaped mask layer 108 having denser meshes is formed on a surface of the pattern transfer layer 109, and the pattern transfer layer 109 is etched based on the mesh-shaped mask layer 108 to transfer a mesh pattern in the mesh-shaped mask layer 108 onto the pattern transfer layer 109, such that the mesh-shaped mask structure 110 having meshes of which a density is multiplied is formed. In this way, process steps are simplified and costs are lowered.

In some embodiments, after the semiconductor structure shown in FIG. 15A and FIG. 15B is obtained, an area of meshes in the pattern transfer layer 109 may be further decreased by using a deposition process. Alternatively, the pattern transfer layer 109 is etched by using a wet etching process and the mesh-shaped structure in the pattern transfer layer 109 is transformed into columnar structures arranged in an array.

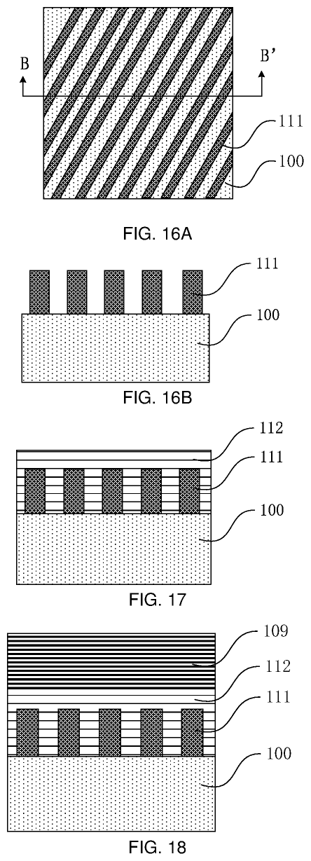

In some embodiments, as shown in FIG. 16A, FIG. 16B, and FIG. 17, before forming the pattern transfer layer 109 on the base 100, the method further includes: forming a patterned hard mask layer 111 having a linear structure on a surface of the base 100, where a trench exists between the linear structures; and forming a hard mask layer 112, where the hard mask layer 112 fills up the trench and covers an upper surface of the patterned hard mask layer 111.

For example, the semiconductor structure manufactured in this embodiment may be a DRAM structure. The patterned hard mask layer 111 having linear structures may be transferred onto the base 100 or the patterned hard mask layer 111 is formed on the base 100, to obtain the structure shown in FIG. 16A and FIG. 16B. The linear structures in the patterned hard mask layer 111 may be formed by using an SAQP process. Optionally, a polycrystalline silicon layer may be further formed between the base 100 and the patterned hard mask layer 111. The linear structures are isolated in a subsequent process, and the base 100 or the polycrystalline silicon layer may be etched based on the isolated linear structures, to form an active array region.

The hard mask layer 112 is formed on the patterned hard mask layer 111. As shown in FIG. 17, the hard mask layer 112 fills up the trench and covers the upper surface of the patterned hard mask layer 111. In some implementations, the hard mask layer 112 may include a carbon layer and a silicon oxynitride layer that are stacked from top to bottom. The carbon layer fills up the trench between the linear structures and covers upper surfaces of all strip-shaped structures; the silicon oxynitride layer is located on an upper surface of the carbon layer.

The pattern transfer layer 109 is formed on the upper surface of the hard mask layer 112, as shown in FIG. 18. For example, the pattern transfer layer 109 may be a silicon oxide layer.

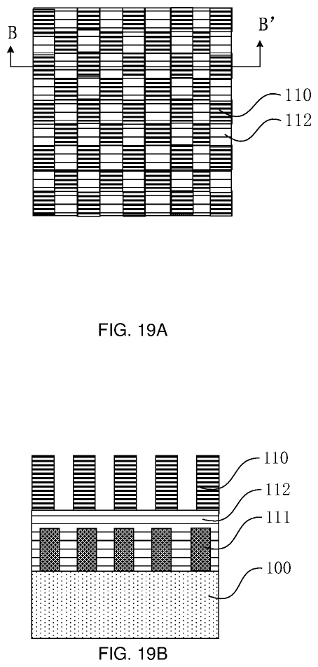

In this embodiment, the mesh-shaped mask structure 110 may be formed in the pattern transfer layer 109 according to the method of manufacturing a semiconductor structure described in the foregoing embodiments, for example, according to step S200 to S400, to obtain the semiconductor structure shown in FIG. 19A and FIG. 19B.

For example, in step S200, the mesh-shaped mask layer 108 may be formed on an upper surface of the pattern transfer layer 109 by using the patterning method according to any one of the foregoing embodiments, where the mesh-shaped mask layer 108 exposes the pattern transfer layer 109.

Specifically, a silicon nitride layer may be first formed on the upper surface of the pattern transfer layer 109, to be served as a first mask layer 101. Then, a first mask 102 is provided to etch the first mask layer 101 until the upper surface of the pattern transfer layer 109 is exposed, to form a first patterned mask layer including a plurality of first mask structures 103. An extension direction of a first straight line mask included in the first mask may be parallel to a bit line in the DRAM structure, and a size of a pitch of the first straight line mask is twice that of a pitch of the bit line, where the pitch represents a distance between center lines of two adjacent same structures. Optionally, a width of a spacing between the first straight line masks and a width of the first straight line mask are the same.

Optionally, to improve quality of the first mask structure 103, a carbon layer and a silicon oxynitride layer that are sequentially stacked may be further formed, as auxiliary mask layers, on an upper surface of the silicon nitride layer. After the first mask structure 103 is formed, the remaining part of the carbon layer and the remaining part of the silicon oxynitride layer are removed.

After the first mask structure 103 is formed, a second mask structure 106 is manufactured based on the first mask structure 103. Specifically, the carbon layer and the silicon oxynitride layer that are sequentially stacked may be formed on upper surface of the first mask structure 103, where the carbon layer fills up a trench between the first mask structures 103 and covers the upper surface of the first mask structure 103, and the silicon oxynitride layer covers an upper surface of the carbon layer. Then, a second mask 105 is provided, and the carbon layer and the silicon oxynitride layer are etched based on the second mask 105. A second straight line mask included in the second mask 105 is parallel to a word line, and a pitch of the second straight line mask is twice a pitch of the word line. The silicon oxynitride layer exposed by the second mask 105 is removed through etching based on the second mask 105. Then, a gas that has a selectivity ratio to only the carbon layer is used to etch the carbon layer until the pattern transfer layer 109 and the first mask structure 103 are exposed. Finally, the remaining part of the silicon oxynitride layer on the carbon layer is removed to obtain the second mask structures 106 arranged at intervals.

To form the mesh-shaped mask layer 108, the first mask structure 103 and the second mask structure 106 further need to be selectively etched. Specifically, a silicon oxide layer may be formed, as a second dielectric layer 107, in a spacing region between the second mask structures 106 and upper surface of the second mask structure 106, and then the silicon oxide layer is etched until the upper surface of the second mask structure 106 is exposed.

Further, because the second mask structure 106 is a carbon layer, a gas that has a selectivity ratio to only carbon is used to etch the second mask structure 106 until the first mask structure 103 (silicon nitride layer) is exposed; then, a gas that has a selectivity ratio to only the silicon nitride layer is used to etch the first mask structure 103 until the pattern transfer layer 109 (silicon oxide layer) is exposed.

The mesh-shaped mask structure 110 can be formed on the pattern transfer layer 109 after the remaining part of the second dielectric layer 107 is removed. In this embodiment, the second dielectric layer 107 and the pattern transfer layer 109 are each a silicon oxide layer. Therefore, alternatively, a gas that has a selectivity ratio to only silicon oxide may be used to etch the silicon oxide layer. In this way, the remaining part of the second dielectric layer 107 may be removed, and the pattern transfer layer 109 may be etched based on the mesh-shaped mask layer 108 to form the mesh-shaped mask structure 110 in the pattern transfer layer 109, where part of the upper surface of the hard mask layer 112 is exposed.

The semiconductor structure shown in FIG. 19A and FIG. 19B can be obtained after the mesh-shaped mask layer 108 including the carbon layer and the silicon nitride layer is removed.

Further, in some embodiments, after removing the mesh-shaped mask layer 108, the method further includes:

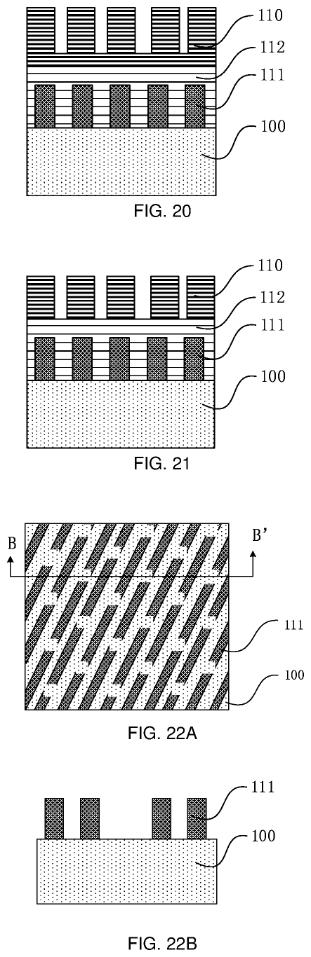

S500: Decrease a size of a mesh in the pattern transfer layer 109, as shown in FIG. 20 and FIG. 21.

For example, a deposition process may be used to deposit silicon oxide on a surface of the pattern transfer layer 109. The deposition process may include but is not limited to an ALD process. As shown in FIG. 20, the ALD process may be used to deposit silicon oxide on the surface of the pattern transfer layer 109. Then, a specific thickness of silicon oxide layer is removed through etching, to expose the upper surface of the hard mask layer 112, as shown in FIG. 21.

S600: Etch the hard mask layer 112 and the patterned hard mask layer 111 based on the pattern transfer layer 109, to cut off the linear structure in the patterned hard mask layer 111, as shown in FIG. 22A and FIG. 22B.

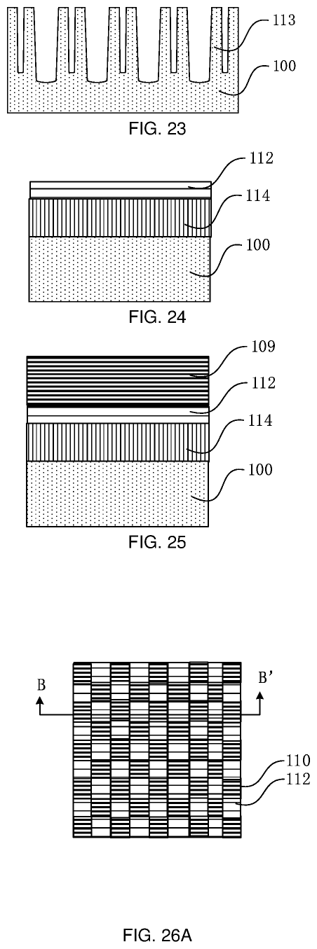

S700: Remove a remaining part of the hard mask layer 112, and etch the base 100 based on an etched patterned hard mask layer 111, to form active regions 113 arranged in an array in the base 100, as shown in FIG. 23.

In the method of manufacturing a semiconductor structure, the mesh-shaped mask structure 110 having meshes of which a density is multiplied is formed based on the method of patterning the foregoing embodiments, and further, the deposition process is used to decrease the size of the mesh, to precisely cut off the linear structures and obtain the required active region 113 array.

In some embodiments, before forming the pattern transfer layer 109, the method further includes: forming a metal layer 114 on the base 100; and forming the hard mask layer 112 on an upper surface of the metal layer 114, as shown in FIG. 24.

In this embodiment, the semiconductor structure may be a DRAM structure, and a word line and a bit line are formed in the base 100. The pattern transfer layer 109 is formed on an upper surface of the hard mask layer 112, as shown in FIG. 25. Similarly, the mesh-shaped mask structure 110 may be formed in the pattern transfer layer 109 by using the method of manufacturing a semiconductor structure in the foregoing embodiments, for example, by using step S200 to S400, to obtain the semiconductor structure shown in FIG. 26A and FIG. 26B. The step of forming the mesh-shaped mask structure 110 in the pattern transfer layer 109 is described in detail in the foregoing embodiment, and herein details are not described again.

Further, after removing the mesh-shaped mask layer 108, the method further includes:

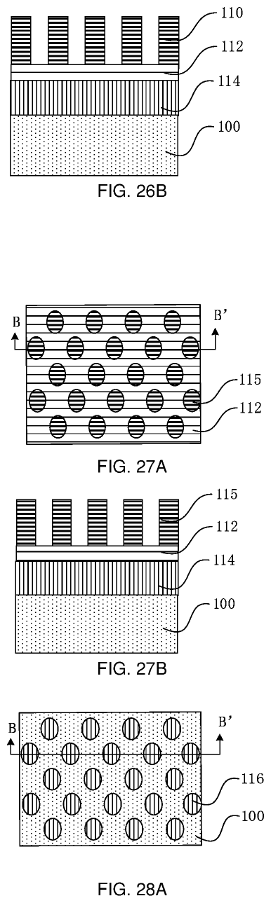

S500′: Etch the pattern transfer layer to form columnar structures 115 arranged in an array, as shown in FIG. 27A and FIG. 27B.

For example, part of silicon oxide in the pattern transfer layer may be removed through etching by using a wet etching process, to form independent columnar structures 115 arranged in an array, as shown in FIG. 27A.

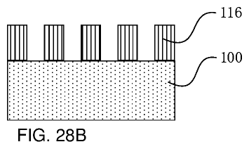

S600′: Etch the hard mask layer 112 and the metal layer 114 based on the columnar structure 115, and remove a remaining part of the hard mask layer 112, to form a metal pad 116, as shown in FIG. 28A and FIG. 28B.

In the method of manufacturing a semiconductor structure, the mesh-shaped mask structure 110 having meshes of which a density is multiplied is formed based on the method of patterning the foregoing embodiments, and further, the mesh-shaped mask structure 110 is etched to form the columnar structures 115 arranged in an array, implementing miniaturization of the columnar structures 115; and the metal layer 114 is etched based on the columnar structures 115 to obtain the metal pad 116 of which a feature dimension is miniaturized.

The technical features of the foregoing embodiments can be employed in arbitrary combinations. To provide a concise description, all possible combinations of all technical features of the foregoing embodiments may not be described; however, these combinations of technical features should be construed as disclosed in this specification as long as no contradiction occurs.

Only several embodiments of the present disclosure are described in detail above, but they should not therefore be construed as limiting the scope of the present disclosure. It should be noted that those of ordinary skill in the art can further make variations and improvements without departing from the conception of the present disclosure. These variations and improvements all fall within the protection scope of the present disclosure. Therefore, the protection scope of the present disclosure should be subject to the protection scope defined by the claims.

1. A patterning method, comprising:
providing a base;
forming a first patterned mask layer on a surface of the base, wherein the first patterned mask layer comprises a plurality of first mask structures extending along a first direction, and the first mask structures are arranged at intervals;
forming a first dielectric layer on the first patterned mask layer, wherein the first dielectric layer fills up a spacing region between the first mask structures and covers an upper surface of the first patterned mask layer; and etching the first dielectric layer to form a plurality of second mask structures extending along a second direction, wherein the second mask structures are arranged at intervals, and the second direction intersects with the first direction; and
selectively etching the first mask structure and the second mask structure, to form a mesh-shaped mask layer on the surface of the base.

2. The patterning method according to claim 1, wherein the forming a first patterned mask layer on a surface of the base comprises:
forming a first mask layer on the surface of the base;
providing a first mask, wherein the first mask comprises a plurality of first straight line masks extending along the first direction, and the first straight line masks are arranged at intervals; and
aligning the first mask with the first mask layer by using a self-aligned process, and removing the first mask layer outside a shielding region of the first mask, to form the first patterned mask layer comprising the first mask structure.

3. The patterning method according to claim 1, wherein the etching the first dielectric layer, to form a plurality of second mask structures extending along a second direction comprises:
providing a second mask, wherein the second mask comprises a plurality of second straight line masks extending along the second direction, and the second straight line masks are arranged at intervals; and
aligning the second mask with the first dielectric layer by using a self-aligned process, and removing the first dielectric layer outside a shielding region of the second mask, to form the second mask structure, wherein a spacing region between the second mask structures exposes the first patterned mask layer and the base.

4. The patterning method according to claim 2, wherein at least one of a density of the first mask structures or a density of the second mask structures is multiplied by using a self-aligned double patterning process or a self-aligned quadruple patterning process.

5. The patterning method according to claim 3, wherein the selectively etching the first mask structure and the second mask structure, to form a mesh-shaped mask layer on the surface of the base comprises:
forming a second dielectric layer, wherein the second dielectric layer fills up the spacing region between the second mask structures and covers an upper surface of the second mask structure;
etching the second dielectric layer until the upper surface of the second mask structure is exposed;
selectively etching the second mask structure until an upper surface of the first mask structure is exposed;
selectively etching an exposed first mask structure until the surface of the base is exposed; and
removing a remaining part of the second dielectric layer to form the mesh-shaped mask layer.

6. The patterning method according to claim 5, wherein the first patterned mask layer comprises a silicon nitride layer, the first dielectric layer comprises a carbon layer, and the second dielectric layer comprises a silicon oxide layer.

7. The patterning method according to claim 1, wherein
a width of a spacing between the first mask structures is equal to a width of the first mask structure; and
a width of a spacing between the second mask structures is equal to a width of the second mask structure.

8. A method of manufacturing a semiconductor structure, comprising:
forming a pattern transfer layer on a base;
forming the mesh-shaped mask layer on an upper surface of the pattern transfer layer by using the patterning method according to claim 1, wherein the mesh-shaped mask layer exposes the pattern transfer layer;
etching the pattern transfer layer based on the mesh-shaped mask layer; and
removing the mesh-shaped mask layer.

9. The method of manufacturing the semiconductor structure according to claim 8, wherein before the forming a pattern transfer layer, the method further comprises:
forming a patterned hard mask layer having a linear structure on the surface of the base, wherein a trench exists between the linear structures; and
forming a hard mask layer, wherein the hard mask layer fills up the trench and covers an upper surface of the patterned hard mask layer.

10. The method of manufacturing the semiconductor structure according to claim 8, wherein before the forming a pattern transfer layer, the method further comprises:
forming a metal layer on the base; and
forming a hard mask layer on an upper surface of the metal layer.

11. The method of manufacturing the semiconductor structure according to claim 9, wherein the semiconductor structure comprises a dynamic random access memory structure, the first direction is parallel to a direction of a bit line in the dynamic random access memory structure, and the second direction is parallel to a direction of a word line in the dynamic random access memory structure.

12. The method of manufacturing the semiconductor structure according to claim 9, wherein after the removing the mesh-shaped mask layer, the method further comprises:
decreasing a size of a mesh in the pattern transfer layer;
etching the hard mask layer and the patterned hard mask layer based on the pattern transfer layer, to cut off the linear structure in the patterned hard mask layer; and
removing a remaining part of the hard mask layer, and etching the base based on an etched patterned hard mask layer, to form active regions arranged in an array in the base.

13. The method of manufacturing the semiconductor structure according to claim 12, wherein the decreasing a size of a mesh in the pattern transfer layer comprises using a deposition process.

14. The method of manufacturing the semiconductor structure according to claim 10, wherein after the removing the mesh-shaped mask layer, the method further comprises:
etching the pattern transfer layer to form columnar structures arranged in an array; and
etching the hard mask layer and the metal layer based on the columnar structure, and removing a remaining part of the hard mask layer, to form a metal pad.

15. The method of manufacturing the semiconductor structure according to claim 14, wherein the etching the pattern transfer layer comprises using a wet etching process.
